(19) United States
(12) Patent Application Publication
(10) Pub. No.: US 2010/0246115 A1
(43) Pub. Date: Sep. 30, 2010

(54) MEMORY CARD ACTUATOR

(75) Inventor: Peter MOGREN, Malmo (SE)

Correspondence Address: WARREN A. SKLAR (SOER);RENNER, OTTO, BOISSELLE & SKLAR, LLP, 1621 EUCLID AVENUE, 19TH FLOOR, CLEVELAND, OH, 44115, US

(73) Assignee: SONY ERICSSON MOBILE COMMUNICATIONS AB, Lund (SE)

(21) Appl. No.: 12/425,786

(22) Filed: Apr. 17, 2009

Related U.S. Application Data
(60) Provisional application No. 61/163,518, filed on Mar. 26, 2009.

(51) Int. Cl. H05K 5/00

(52) U.S. Cl. 361/679.31

(57) ABSTRACT

A portable electronic device comprises a card actuator for ejection and introduction of memory cards and a card holder with a card eject mechanism for ejecting a memory card in a first direction if the card is moved in a second direction, which card actuator is adapted for interaction with the card for moving the card in the second direction, and the card actuator is fixedly connected to the portable electronic device.

### TECHNICAL FIELD OF THE INVENTION

The present invention relates to a card actuator for facilitating ejecting and/or introducing memory cards used in card readers, such as smart cards. The memory card actuator may advantageously be used in an electronic device having or being connected to such a card reader.

### DESCRIPTION OF RELATED ART

Today, there exist various ways of facilitating the ejection of external cards with memories used in portable electronic devices. Moreover, there exist different types of memory cards with differing sizes for different portable electronic devices, such as mobile telephones, smart phones, lap tops, communicators, cameras, digital audio players (e.g. MP3-players or iPods®), electronic photo frames, etc. The memory cards may be different types of memory or smart cards, e.g. removable SIM cards and flash memory cards known as Memory Sticks, e.g. the memory card can be a Memory Stick Micro (M2) being compatible only with some Sony Ericsson phones. This M2 card is approximately one-quarter the volume of another type of memory card, i.e. a Memory Stick PRO or a Memory Stick PRO Duo, and only about 1.2 mm thick. The M2 memory card is designed as an externally removable and very small card that is actuated when ejected from or introduced into the electronic device by a controlled and biased eject/introduction function in a card holder or reader to prevent users losing the card. The actuator for introducing or ejecting a memory card is a known device using push-push or push-pull ejectors and will not be explained in more detail.

There are card readers equipped with such an ejecting actuator available for PC and other portable devices, e.g. the ones mentioned above and Sony's portable play station (PSP), for reading memory cards, by connecting via USB, whereby data in the card can be transferred to or from the electronic device easily.

Consequently, there are currently many different memory cards for the usage together with portable electronic devices, and some cards are smaller than others. This may give rise to problems for a user, since the smaller a memory card the more difficult to keep track of and handle. Hence, there is a need of simple and quick ways of introducing and/or ejecting small memory cards from a card reader. This is due to the fact that the size of the edge of the memory card to be ejected or introduced and the associated card reader slot in general is smaller than the user's finger. Furthermore, some of the known eject mechanisms require a separate tool to be operated, e.g. Shiho. This involves an increased cost for the manufacturer of the portable electronic device as a certain additional volume of the device in general is dedicated for accommodating the separate removable tool making the device larger than necessary. Furthermore, the user has to push the card with his finger being much bigger than the card and/or use the separate, loose tool, pin or pen to be able to “hit” the thin edge of the card when pushing the card to eject or introduce it. Yet further, when a portable electronic device is to be equipped with a separate, loose tool for ejection or introduction of the memory card, the handling and size of the portable electronic device due to the loose tool are compromised. Moreover, if a electronic portable device of a desirable small size is used with more than one separate and loose item, i.e. at least one loose memory card and one loose tool for ejecting and/or introducing the card, there is a risk that either the memory card and/or the tool, when the tool is not in use, can be lost.

### SUMMARY OF THE INVENTION

It has therefore, with the above and the following description in mind, and in view of an aspect of the present invention to provide an improved device, which seeks to mitigate, alleviate or eliminate one or more of the above-identified deficiencies in the art and disadvantages singly or in any combination.

The present invention is defined by the appended independent claims. Various advantageous embodiments of the invention are set forth by the appended dependent claims as well as by the following description and the accompanying drawings.

An aspect of the present invention relates to a portable electronic device comprising a card actuator and a card holder with a card eject mechanism for ejecting a card in a first direction if the card is moved in a second direction, which card actuator is adapted for interaction with the card for moving the card in the second direction, and the card actuator is fixedly connected to the portable electronic device.

An aspect of the present invention relates to a portable electronic device, wherein a lid is movably and fixedly connected to the portable electronic device for coverage of and access to a card holder of the portable electronic device.

Another aspect relates to a portable electronic device, wherein the card actuator is an integrated part of a lid of the portable electronic device. In another aspect, the card actuator of the portable electronic device is a projection of the lid.

An aspect relates to a portable electronic device, wherein the card actuator, when not in use, is accommodated in a cavity of the portable electronic device, which cavity is located adjacent a card holder of the portable electronic device.

An aspect relates to a portable electronic device, wherein the card actuator has an elongated flexible body.

Another aspect relates to a portable electronic device, wherein the elongated body has one free end, which is provided with a card actuating tip.

An aspect relates to a portable electronic device, wherein the elongated body of the card actuator has a varying shape lengthwise.

Another aspect relates to a portable electronic device, wherein the elongated body of the card actuator has a substantially cylindrical shape with a varying diameter.

An aspect relates to a portable electronic device, wherein the card actuator has a rod-like shape.

An aspect relates to a portable electronic device, wherein a card actuator is intended for the usage together with the portable electronic device, wherein the portable electronic device is a device from the group comprising: a mobile radio terminal, a mobile telephone, a cellular telephone, a pager, a communicator, a smart phone, a Personal Digital Assistant (PDA), an electronic organizer, a computer, a digital audio player or a digital camera.

An aspect relates to a portable electronic device comprising a memory card being adapted to be ejected from a card holder of the portable electronic device by means of a card actuator.

An aspect relates to a portable electronic device, wherein the memory card is adapted to be loaded into a card holder of the portable electronic device by means of a card actuator.

Thus, the portable electronic device according to the invention comprises an integrated card actuator that serves as a smart built-in-device having two functions, i.e. being able to facilitate the ejection of the memory card from the card holder or reader and/or to facilitate the introduction of the same into the card reader. It is an advantage with the invention that no separate tool is necessary for operating the card actuator, whereby there are fewer items to keep track of and handle. Thus, also the total cost for manufacturing the electronic device using such a card actuator may be reduced. Furthermore, the risk for loosing various items, such as the separate loose tool for ejection of the memory card may be limited, since there are fewer items to keep track of and to handle, i.e. only the memory card must be kept track of, whereby the risk of loosing the card ejection tool is eliminated.

### BRIEF DESCRIPTION OF THE DRAWINGS

Further objects, features and advantages of the invention will appear from the following detailed description of the invention, wherein the invention will be described in more detail with reference to the accompanying drawings, in which:

FIG. 1 show a portable electronic device according to the invention when its integrated card actuator is not used;

FIG. 2 shows a side view of a part of the portable electronic device shown in FIG. 1 when its integrated card actuator is to be used or has been used;

FIG. 3 shows another side view of the portable electronic device shown in FIGS. 1 and 2 when its integrated card actuator is to be used or has been used;

FIG. 4 shows yet another side view of the portable electronic device shown in FIGS. 1 to 3 when its integrated card actuator is to be used or has been used;

FIG. 5 shows still another side view of the portable electronic device shown in FIGS. 1 to 4 when its integrated card actuator is to be used or has been used;

FIG. 6 shows another side view of the portable electronic device shown in FIG. 4 when its integrated card actuator is used, and

FIG. 7 shows yet another side view of the portable electronic device shown in FIGS. 4 and 6 when its integrated card actuator is not used, but stored.

### DETAILED DESCRIPTION OF EMBODIMENTS

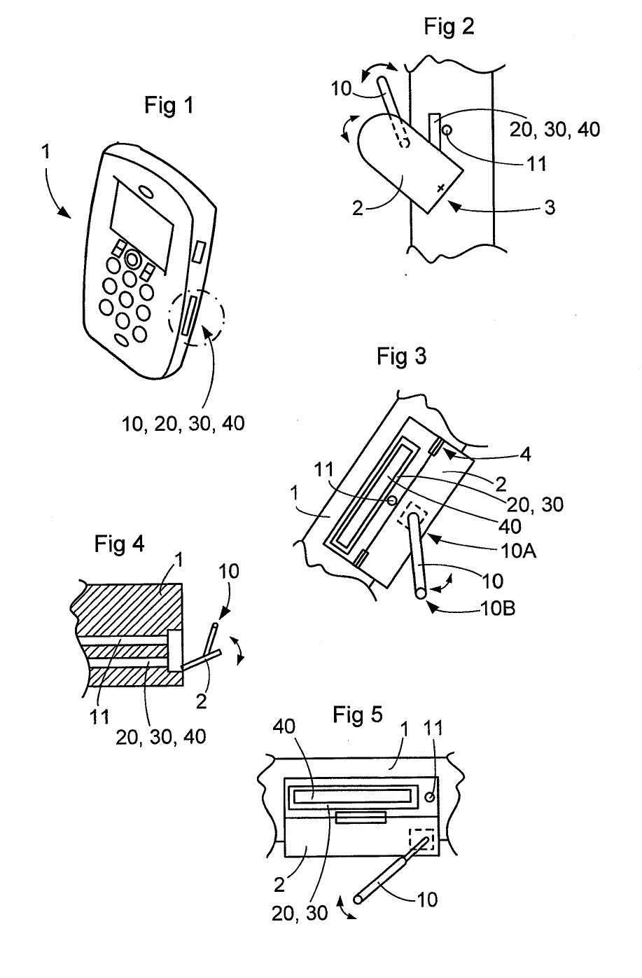

Aspects of the present invention will be described more fully hereinafter with reference to the accompanying drawings. FIGS. 1-7 show different views of the portable electronic device 1 comprising a card actuator 10 according to different aspects of the invention. This invention may, however, be embodied in many different forms and should not be construed as limited to the examples set forth herein. Rather, these examples are provided so that this disclosure will be thorough and complete, and will fully convey the scope of the invention to those skilled in the art. Like numbers refer to like elements throughout.

The card actuator 10 according to the portable electronic device 1 of the disclosed invention is preferably, but not necessarily, intended for the usage together with the portable electronic device 1 (see FIG. 1) having a memory card reader or holder 20. The portable electronic device may be any portable electronic device such as, e.g., a mobile radio terminal, a mobile telephone, a cellular telephone, a pager, a communicator, a smart phone, a Personal Digital Assistant (PDA), an electronic organizer, a computer, a digital audio player such as a MP3-player or an iPod®, a digital camera, an electronic picture frame, a television receiver, A Home cinema, or any other suitable picture or movie projector.

The card actuator 10 may comprise a single elongated body in the form of a rod-like body with one end fixed to a movable lid 2 for access to the card holder 20 in the electronic device 1. The card holder comprises an integrated card eject mechanism 30 being adapted for enabling easy ejection of a memory card 40 from the card holder. The function of the card holder 20 and the card eject mechanism 30 are known technology and will not be explained in more detail. The lid 2 has the function of closing and opening the card holder 20 in a known way for introduction or removal of the memory card 40. The card eject mechanism 30 may of course also be used for loading, i.e. introducing the memory card 40 into the card reader 20 in a known way, and this function will also not be explained in more detail. Moreover, the card reader may be placed on one long side edge of the electronic device 1. The card reader may of course also be arranged at any other suitable location on and/or in the electronic device as long as easy access to the lid 2 for opening and closing is enabled: Alternatively, the card reader may be arranged on the opposite long side edge. The card reader may as an alternative be placed on a short side of the electronic device 1. The card reader may alternatively be placed at the back of the electronic device 1. The card reader may also be placed at the front of the electronic device. The lid 2 of the electronic device may also enable access to a cavity 11 for accommodating the card actuator 10 when not in use. The cavity 11 of the electronic device may as an alternative be located adjacent the card reader 20. Alternatively, the card actuator 10 is an integrated part of the lid 2. In an alternative, the card actuator is a projection of the lid.

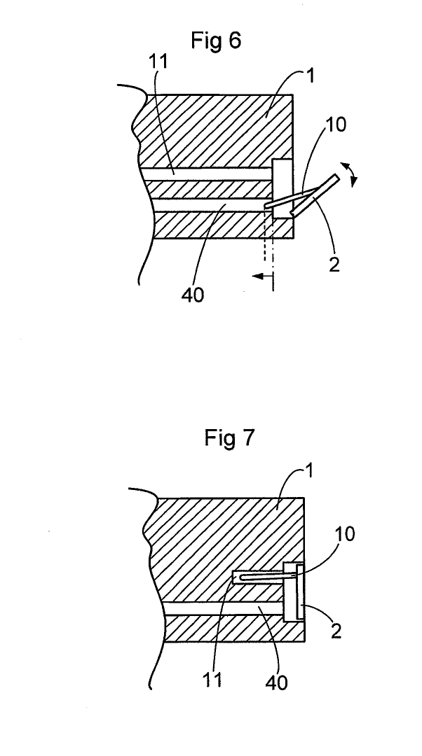

The card actuator 10 is fixedly connected to the portable electronic device 1. The card actuator 10 is alternatively being fixed with one end 10A to the inside of the lid 2. The card actuator may alternatively have one free end or tip 10B for interaction with the memory card 40 by being adapted to contact the memory card. The card actuator is designed such that a user of the electronic device can eject the card in a first direction by pushing and moving the card in a second direction. This is done in that the user firstly opens the lid 2, then grabs and handles the card actuator 10 manually for moving the free actuator end 10B into contact with the card 40 as shown in FIG. 6, and pushes the card by means of the free actuator end 10B in the second direction shown with the arrow in FIG. 6, such that the card eject mechanism 30 is actuated and ejects the card in the first direction opposite the second direction, i.e. in the opposite direction of the arrow in FIG. 6.

When the memory card 40 is to be introduced into an empty card holder 20 of the electronic device 1, firstly, the lid 2 is opened (if closed), the card placed at least partly inside the slot of the card reader, the card actuator 10 is grabbed and handled (see explanation for ejection) for moving the free actuator end 10B into contact with the card (in a similar way as shown in FIG. 6, but, here, the card end is exposed at least partly outside the card holder (not shown), and pushes the card by means of the free actuator end in the second direction shown with the arrow in FIG. 6, such that the card eject mechanism 30 is actuated into its holding state for keeping the card loaded in place inside the card holder 20 and the electronic device until an card ejection is performed.

The card actuator 10 may be flexible such that it may be bent for enabling its free end 10B to contact the card 40 for ejection or introduction thereof. Alternatively, the fixed end 10A of the card actuator is flexibly connected to the lid 2 such that the free actuator end 10A may be moved into contact with the card for ejection or introduction thereof. Furthermore, the lid 2 may alternatively be movably and flexibly connected to the electronic device 1 such that the flexibility of the card actuator 10 and the flexible connection between the lid and the electronic device enables the free actuator end 10A to be moved into contact with the card 40 for ejection or introduction thereof. Moreover, the lid 2 may as an alternative be movably connected to the electronic device by means of an extendible connection such that both the lid and the card actuator 10 is movable enabling the free actuator end 10A to be moved into contact with the card for ejection or introduction thereof.

Furthermore, as can be seen in FIGS. 2, 3, and 5, the card actuator 10 may be fixed to the lid 2 at different locations. In FIG. 2, the card actuator end 10A may as an alternative be arranged at the middle portion of the lid but closer to one long side of the lid compared to the position shown in FIG. 3. In this position of FIG. 3, the fixed card actuator end may alternatively be arranged closer to the lid centre. FIG. 5 shows another position where the fixed card actuator end may as an alternative be arranged at one short side of the lid. Moreover, the lid may have different shapes and connections to the electronic device 1. e.g. the lid in FIG. 2 may be attached by means of a pivot 3 at its short side so that the lid is opened by a pendulum like movement. Alternatively, the lid in FIGS. 3 and 5 may be attached by means of hinges 4. Hence, two hinges spaced apart in FIG. 3 in one alternative and one central hinge in FIG. 5 in another alternative. In FIGS. 3 and 5, the lid is opened and closed in the similar way as a door in a building. The cavity 11 for storage of the card actuator when not in use (see FIG. 7) may be arranged in the electronic portable device 1 such that its location corresponds to the different arrangements of the card actuator 10 for enabling its free end 10B to be introduced into the cavity firstly, followed by the whole actuator length, such that, when the lid 2 is closed, the card actuator 10 is fully introduced into the cavity 11. The actuator may be taken out from the cavity 11 by first opening the lid 2, whereby at least a part of the actuator is pulled out, and may then be grabbed by the user for manually pulling out the whole actuator length so that the free end 10B is accessible for use.

As shown in FIGS. 2 to 4, the card actuator 10 may be formed as a rod or pin with a substantially cylindrical form. Alternatively, in FIG. 5, the card actuator may have a varying shape lengthwise, e.g. a varying diameter. In FIG. 5, as an alternative, the diameter at the fixed end 10A may be smaller than the diameter at the free end 10B. The diameter could alternatively be larger at the fixed end 10A instead. This depends on the desired flexibility of the card actuator as its flexibility can be controlled by choosing different physical properties, dimensions, and/or material when designing the card actuator 10. As an alternative, the flexibility of the lid 2 can be controlled by choosing different physical properties, dimensions, and/or material when designing the lid such that the interacting lid and card actuator 10 is sufficiently flexible to be able to cooperate for ejecting or introducing the smart card, i.e. such that the free card actuator end 10B may contact the smart card for this. The smaller diameter at end 10A is one way of achieving flexibility in the card actuator 10. This varying shape may alternatively be achieved as shown in FIG. 5 by making a distinct intermediate middle portion. This may as an alternative be done by making a continuous diameter variation. One example being a conical shape (not shown). Another way is to make the card actuator 10 in FIGS. 2 to 4 of a flexible or elastic material. Alternatively, the same can be done for the lid 2 and its connection to the electronic device 1. Alternatively (not shown), the card actuator 10 could be formed as a spring. One example being a coiled spring. Alternatively, the elongated body of the actuator 10 may be coiled into a substantially helical shape. In this form, the card actuator may be bendable but sufficiently stiff such that the free actuator end 10B does not deform or bend when being used to push the card 40. Moreover, the card actuator may as an alternative be made of a metal suitable for a coiled form.

The card actuator 10 may alternatively be integrally attached to the lid 2 by any fastening means for flexible connection thereto, preferably by moulding.

The elongated body 10 may be in the form of a cylindrical rod. This rod may alternatively be relatively thin while at the same time enabling an easy and secure handling so that a small memory card is easy to “hit” at the thin card edge for ejection or introduction. Furthermore, the elongated card actuator body 10 and the lid 2 can as an alternative be made of various materials, but does not necessarily have to be made of the same material, even though this is preferred for moulding, as it is possible to mould them in different materials with differing properties. For example, the elongated body 10 may be made of a polymer material such as synthetic rubber or a metal suitable for a coiled spring form.

As described earlier, the card actuator 10 may be intended for the usage together with a portable electronic device 1, such as a the mobile telephone as illustrated in FIG. 1, and has the further advantage that the card actuator makes the hands free handling of the portable electronic device easier as one less item, i.e. the separate and loose tool is eliminated such that the user has fewer items to store and handle manually.

The present invention has been described above with reference to a specific aspect. Many modifications can be made by a person skilled in the art. The aspects described above is merely an illustrative example and the invention can be modified and used together with many different products, not only portable electronic devices as indicated in the detailed description. The different features of the invention can be combined in other combinations than those described. The invention is only limited by the appended claims

1. A portable electronic device comprising a card actuator and a card holder with a card eject mechanism for ejecting a card in a first direction if the card is moved in a second direction, which card actuator is adapted for interaction with the card for moving the card in the second direction, and the card actuator is fixedly connected to the portable electronic device.

2. The portable electronic device as recited in claim 1, wherein a lid is movably and fixedly connected to the portable electronic device for coverage and access to the card holder, and the card actuator is an integrated part of the lid.

3. The portable electronic device as recited in claim 2, wherein the card actuator is a projection of the lid.

4. The portable electronic device as recited in claim 1, wherein the card actuator, when not in use, is adapted for accommodation in a cavity of the portable electronic device, which cavity is located adjacent the card holder.

5. The portable electronic device as recited in claim 2, wherein the card actuator, when not in use, is adapted for accommodation in a cavity of the portable electronic device, which cavity is located adjacent the card holder.

6. The portable electronic device as recited in claim 1, wherein the card actuator has an elongated flexible body.

7. The portable electronic device as recited in claim 6, wherein the elongated body of the card actuator has one free end, which is provided with a card actuating tip.

8. The portable electronic device as recited in claim 6, wherein the elongated body of the card actuator has a varying shape lengthwise.

9. The portable electronic device as recited in claim 8, wherein the elongated body of the card actuator has a substantially cylindrical shape with a varying diameter.

10. The portable electronic device as recited in claim 6, wherein the card actuator has a rod-like shape.

11. The portable electronic device as recited in claim 1, wherein the card actuator is intended for the usage together with the portable electronic device, wherein the portable electronic device is a device from the group comprising: a mobile radio terminal, a mobile telephone, a cellular telephone, a pager, a communicator, a smart phone, a Personal Digital Assistant (PDA), an electronic organizer, a computer, a digital audio player or a digital camera.

12. The portable electronic device as recited in claim 11 comprising a memory card being adapted to be ejected from a card holder of the portable electronic device by means of the card actuator.

13. The portable electronic device as recited in claim 12, wherein the memory card is adapted to be loaded into the card holder by means of the card actuator.
